(19) United States
(12) Patent Application Publication
(10) Pub. No.: US 2008/0142845 A1
(43) Pub. Date: Jun. 19, 2008

(54) HEMT including MIS structure

(75) Inventors: Masahito KODAMA, Komaki-shi (JP); Eiko HAYASHI, Seto-shi (JP); Tsutomu UESUGI, Seto-shi (JP); Masahiro SUGIMOTO, Toyota-shi (JP)

Correspondence Address: FINNEGAN, HENDERSON, FARABOW, GARRETT & DUNNER;LLP, 901 NEW YORK AVENUE, NW, WASHINGTON, DC, 20001-4413, US

(73) Assignee: Toyota Jidosha Kabushiki Kaisha

(21) Appl. No.: 12/000,528

(22) Filed: Dec. 13, 2007

(30) Foreign Application Priority Data
Dec. 13, 2006 (JP) 2006-336208

(51) Int. Cl. H01L 29/778

(52) U.S. Cl. 257/194; 257/E29.246

(57) ABSTRACT

A HEMT has a drain region adapted to be electrically connected to a high voltage of an electric source, a source region adapted to be electrically connected to a low voltage of the electric source. A first semiconductor region is disposed between the drain region and the source region. A MIS structure and a heterostructure are disposed at a surface of the first semiconductor region. The MIS structure includes a gate electrode that faces a portion of a surface of the first semiconductor region with a gate insulating membrane therebetween. The heterostructure includes a second semiconductor region which makes contact with a rest portion of the surface of the first semiconductor region and has a wider band-gap than the first semiconductor region. The drain region and the source region are capable of being electrically connected with a structure in which the MIS structure 40 and the heterostructure are arranged in series.

### CROSS REFERENCE TO RELATED APPLICATION

This application claims priority to Japanese Patent Application No. 2006-336208 filed on Dec. 13, 2006, the contents of which are hereby incorporated by reference into the present application.

### BACKGROUND OF THE INVENTION

1. Field of the Invention

The present invention relates to a HEMT (High Electron Mobility Transistor) that includes a MIS (Metal Insulator Semiconductor) structure.

2. Description of the Related Art

A HEMT with a heterostructure disposed between a drain region and a source region is being developed. A heterostructure has a structure of stacked layers of semiconductor regions of band gaps having different width. The heterostructure is capable of forming a two-dimensional electron gas layer at its heterojunction plane. For this reason, with the heterostructure disposed between the drain region and the source region, the electron can move from the source region to the drain region through the two-dimensional electron gas layer at high speed and with low resistance.

By selecting a group-III nitride semiconductor as the semiconductive material, a highly concentrated two-dimensional electron gas layer can be formed at the heterojunction plane. Furthermore, by selecting a group-III nitride semiconductor as the semiconductive material, a high electric breakdown field and high temperature operation can be achieved. A HEMT made with group-III nitride semiconductor with a heterostructure is expected to be applied not only to devices designated for use with high frequency, but also to power devices that switch high electric voltage and current.

The Japanese Patent Application Publication No. 2003-51508 discloses a HEMT using gallium nitride (GaN) as its semiconductive material. In the description below, the aforementioned HEMT will be described as the conventional HEMT. In the conventional HEMT, the heterostructure is disposed between the drain region and the source region. The heterostructure extends consecutively between the drain region and the source region, thus being capable of connecting the drain region and the source region. The conventional HEMT further includes a gate electrode that is arranged so as to face a part of the heterostructure.

### BRIEF SUMMARY OF THE INVENTION

Depending on whether voltage is applied to the gate electrode, the conventional HEMT switches between the on and off state. Since the heterostructure is consecutively formed between the drain region and the source region within the conventional HEMT, a two-dimensional electron gas layer is formed consecutively between the drain region and the source region when voltage is not applied to the gate electrode. For this reason, the conventional HEMT functions under a normally-on state. To switch the conventional HEMT off, at least a part of the aforementioned two-dimensional electron gas layer formed at the heterojunction plane has to be vanished. In the conventional HEMT, part of the two-dimensional electron gas layer formed on the heterojunction plane is vanished by applying negative voltage to the gate electrode. When the negative voltage is applied to the gate electrode, the heterojunction plane that faces the gate electrode is depleted, and a part of the two-dimensional electron gas layer that corresponds to the depleted section vanishes. Thus, the conventional HEMT is switched off by applying negative voltage to the gate electrode.

If an undesired condition occurs with the circuit that generates gate voltage, and negative gate voltage cannot be generated, it becomes impossible to switch off the normally-on type HEMT. Certainty of function must be guaranteed. For this reason, a HEMT that functions under a normally-off state is desired. The technique disclosed in the present specification aims to provide a novel configuration of a HEMT with heterostructure that functions under the normally-off state.

The HEMT disclosed in the present specification is characterized in that a MIS structure is disposed on at least a portion between a high voltage side region and a low voltage side region. That is, the HEMT disclosed in the present specification is capable of connecting the high voltage side region and the low voltage side region using a combination of the MIS structure and the heterostructure. The heterostructure of the HEMT disclosed in the present specification does not extend consecutively between the high voltage side region and the low voltage side region. The HEMT disclosed in the present specification does not connect the high voltage side region and the low voltage side region solely by using the heterostructure.

In a case where the high voltage side region and the low voltage side region are connected by using the combination of the MIS structure and the heterostructure arranged therebetween in series, a channel formed by the MIS structure and a two-dimensional electron gas layer formed by the heterostructure exist in series between the high voltage side region and the low voltage side region. In the channel formed by the MIS structure, carriers are inducted when voltage is applied to the gate electrode of the MIS structure. The carriers are not inducted if no voltage is applied thereupon. In the two-dimensional electron gas layer, carriers exist at all times. Hence, the HEMT disclosed in the present specification is in the on-state when voltage is applied to the gate electrode of the MIS structure while it is in the off-state when the voltage is not applied to the gate electrode of the MIS structure. The HEMT disclosed in the present specification is capable of functioning under the normally-off state.

The HEMT disclosed in the present specification comprises a high voltage side region adapted to be electrically connected to a high voltage of an electric source, and a low voltage side region adapted to be electrically connected to a low voltage of the electric source. A first semiconductor region is disposed between the high voltage side region and the low voltage side region. A MIS structure and a heterostructure are disposed at a surface of the first semiconductor region. The MIS structure includes a gate electrode and an insulating region. The material used for the gate electrode is not restricted to metal. Any kinds of conductors may be used for the gate electrode. The gate electrode faces a portion of the surface of the first semiconductor region with the insulating region therebetween. The heterostructure includes a second semiconductor region which makes contact with a rest portion of the surface of the first semiconductor region. The second semiconductor region has a wider band-gap than the first semiconductor region. In the HEMT disclosed in the present specification, the high voltage side region and the low voltage side region are capable of being electrically connected with a structure in which the MIS structure and the heterostructure are arranged in series.

The technique disclosed in the present specification is able to provide a HEMT of a vertical type. The vertical HEMT disclosed in the present specification comprises a high voltage side region adapted to be electrically connected to a high voltage of an electric source, a first semiconductor region disposed on the high voltage side region, and a low voltage side region disposed on the first semiconductor region and adapted to be electrically connected to a low voltage of the electric source. The low voltage side region is separated from the high voltage side region by the first semiconductor region. The vertical HEMT disclosed in the present specification further comprises a columnar region penetrating the first semiconductor region and extending between the high voltage side region and the low voltage side region. The columnar region comprises a MIS structure and a heterostructure arranged in series. The MIS structure includes a gate electrode and an insulating region. The gate electrode faces a portion of a side surface of the first semiconductor region with the insulating region therebetween. The heterostructure includes a second semiconductor region which makes contact with a rest portion of the side surface of the first semiconductor region. The second semiconductor region has a wider band-gap than the first semiconductor region. In the vertical HEMT disclosed in the present specification, the high voltage side region and the low voltage side region are capable of being electrically connected with a structure in which the MIS structure and the heterostructure are arranged in series.

In the aforementioned HEMT of the vertical type, the high voltage side region and the low voltage side region are vertically arranged with the first semiconductor region disposed therebetween. Between the high voltage side region and the low voltage side region, the MIS structure and the heterostructure are vertically arranged in series. In the channel formed by the MIS structure, carriers are inducted when voltage is applied to the gate electrode of the MIS structure, while the carriers are not inducted when no voltage is applied thereupon. Thus, the aforementioned HEMT of the vertical type is capable of functioning under normally-off state, and also of conducting the current in the vertical direction.

It is preferable that the semiconductive material of the HEMT disclosed in the present specification is of group-III nitride semiconductor. The group-III nitride semiconductor can generally be expressed in the formula: AlₓGa_{Y}In_{1-X-Y}N (0≦X≦1, 0≦Y≦1, 0≦1-X-Y≦1).

### BRIEF DESCRIPTION OF THE DRAWINGS

FIG. 1 shows a schematic sectional view of the relevant part of the HEMT of the first embodiment.

FIG. 2 shows a schematic plane view of the relevant part of the HEMT of the first embodiment.

FIG. 3 shows a process (1) of producing the HEMT of the first embodiment.

FIG. 4 shows a process (2) of producing the HEMT of the first embodiment.

FIG. 5 shows a process (3) of producing the HEMT of the first embodiment.

FIG. 6 shows a process (4) of producing the HEMT of the first embodiment.

FIG. 7 shows a schematic sectional view of the relevant part of the HEMT of the second embodiment.

FIG. 8 shows a process (1) of producing the HEMT of the second embodiment.

FIG. 9 shows a process (2) of producing the HEMT of the second embodiment.

FIG. 10 shows a process (3) of producing the HEMT of the second embodiment.

FIG. 11 shows a process (4) of producing the HEMT of the second embodiment.

FIG. 12 shows a process (5) of producing the HEMT of the second embodiment.

FIG. 13 shows a schematic sectional view of the relevant part of a variant of the HEMT of the second embodiment.

FIG. 14 shows a process (1) of producing the variant of the HEMT of the second embodiment.

FIG. 15 shows a process (2) of producing the variant of the HEMT of the second embodiment.

### DETAILED DESCRIPTION OF THE INVENTION

### First Embodiment

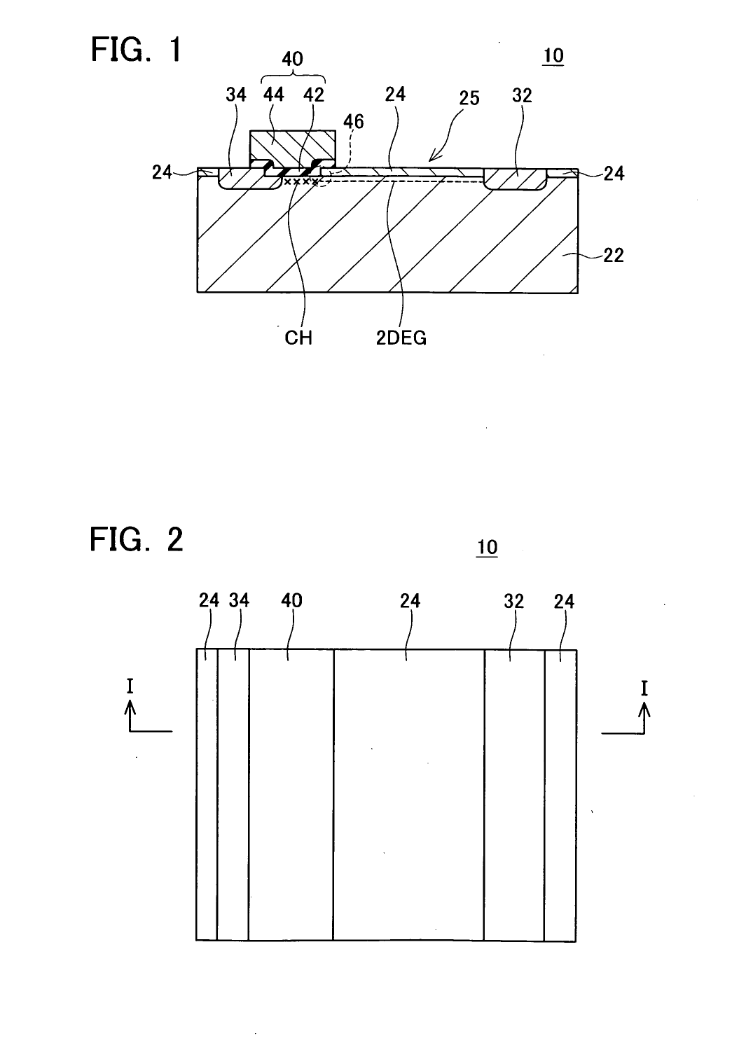

FIG. 1 shows a schematic sectional view of the relevant part of the HEMT 10. FIG. 2 shows a schematic plane view of the relevant part of the HEMT 10. The sectional view of the section indicated with the arrowed line I-I of FIG. 2 corresponds to the sectional view of FIG. 1.

The HEMT 10 comprises a first semiconductor region 22 composed of gallium nitride (GaN), and a second semiconductor region 24 composed of aluminum gallium nitride (AlGaN) that is formed on the first semiconductor region 22. The process of producing the first semiconductor region 22 does not include a step of intentionally introducing impurity thereto. The concentration of impurity of the first semiconductor region 22 is maintained at a level less than 1×10¹⁴ cm⁻³. The second semiconductor region 24 may or may not be introduced with impurities of n type. The second semiconductor region 24 includes aluminum within the composition of the crystal. Thus, the band-gap of the second semiconductor region 24 is wider than that of the first semiconductor region 22. The thickness of the second semiconductor region 24 is about 25 nm. The first semiconductor region 22 and the second semiconductor region 24 form the heterostructure 25.

The HEMT 10 further comprises a drain region 32 (which is an example of a high voltage side region) and a source region 34 (which is an example of a low voltage side region). The drain region 32 penetrates the second semiconductor region 24 and reaches the first semiconductor region 22. The drain region 32 is a n⁺-type region introduced with a highly concentrated silicon, whose concentration of impurity is about 1×10²⁰ cm⁻³. A drain electrode not shown in the figures is connected to the drain region 32. The drain electrode is adapted to be electrically connected to a high voltage of an electric source also not shown in the figures. The source region 34 penetrates the second semiconductor region 24 and reaches the first semiconductor region 22. The source region 34 is a n⁺-type region introduced with a highly concentrated silicon, whose concentration of impurity is about 1×10²⁰ cm⁻³. A source electrode not shown in the figures is connected to the source region 34. The source electrode is adapted to be electrically connected to a low voltage of the electric source.

The HEMT 10 further comprises a MIS structure 40. The MIS structure 40 is in contact with a portion of a surface of the first semiconductor region 22 that extends in between the drain region 32 and the source region 34. The MIS structure 40 is also in contact with the source region 34. The MIS structure 40 includes a gate insulating membrane 42 and a gate electrode 44. The gate electrode 44 faces the portion of the surface of the first semiconductor region 22 with the gate insulating membrane 42 therebetween. Thus, the gate electrode 44 is electrically insulated from the first semiconductor region 22 and the second semiconductor region 24. Silicon dioxide (SiO₂) is used for the gate insulating membrane 42. The thickness of the gate insulating membrane 42 is about 50 nm. A polysilicon is used for the gate electrode 44.

As shown in FIG. 2, the MIS structure 40 is arranged limited area between the drain region 32 and the source region 34, however the MIS structure 40 extends in parallel with the source region 34 and the drain region 32 consecutively along the entire length of the source region 34 and the drain region 32. The second semiconductor region 24 arranged between the drain region 32 and the source region 34 does not consecutively extend between the drain region 32 and the source region 34. The second semiconductor region 24 is hindered from directly connecting the drain region 32 and the source region 34 by the existence of the MIS structure 40. In another words, the drain region 32 and the source region 34 are capable of being connected with a structure in which the MIS structure 40 and the heterostructure 25 are arranged in series.

The function and configuration of the HEMT 10 will be described below. The band-gap of the second semiconductor region 24 is wider than the band-gap of the first semiconductor region 22. For this reason, as shown in FIG. 1, a two-dimensional electron gas layer (2DEG) is formed at the heterojunction plane of the first semiconductor region 22 and the second semiconductor region 24. Of the heterojunction plane, the two-dimensional electron gas layer (2DEG) is formed on the first semiconductor region 22 side.

As mentioned before, the heterostructure 25 that is composed with the first semiconductor region 22 and the second semiconductor region 24 is not extended in all of the portions between the drain region 32 and the source region 34. The MIS structure 40 is arranged between the drain region 32 and the source region 34. Hence, on the surface of the first semiconductor region 22 where the MIS structure 40 is disposed, the two-dimensional electron gas layer (2DEG) is not formed. Thus, the two-dimensional electron gas layer (2DEG) is not consecutively extended in all of the portions between the drain region 32 and the source region 34.

On the surface of the first semiconductor region 22 where the MIS structure 40 is arranged, a channel (CH) is formed with the voltage applied to the gate electrode 44. The channel (CH) is not inducted when voltage is not applied to the gate electrode 44. The channel (CH) is inducted when positive gate voltage is applied to the gate electrode 44. In a case where the channel (CH) is inducted, the interval in between the drain region 32 and the source region 34 is electrically connected with the series of the channel (CH) and the two-dimensional electron gas layer (2DEG). When the channel (CH) and the two-dimensional electron gas layer (2DEG) are consecutively connected in series, the electrons are able to move between the drain region 32 and the source region 34.

Thus, the HEMT 10 is switched off when no voltage is applied to the gate electrode 44, while the HEMT 10 is switched on when positive voltage is applied to the gate electrode 44. The HEMT 10 is able to function under the normally-off state.

Other characteristics of the HEMT 10 are described below.

(1) In the HEMT 10, the impurity concentration of the first semiconductor region 22 is maintained at a level less than 1×10¹⁴ cm⁻³. The first semiconductor region 22 having the aforementioned impurity concentration can substantially be regarded as an insulator. For such a configuration, the electric field strength in between the drain region 32 and the MIS structure 40 is leveled. Localized electric field concentration can be prevented. Especially, as indicated in FIG. 1, the electric field concentration at the corner section 46 of the gate insulating membrane 42 of the MIS structure 40 can be effectively relieved. As its result, the destruction of the gate insulating membrane 42 is prevented. Even in a case where the impurity concentration of the first semiconductor region 22 is less than 1×10¹⁴ cm⁻³, the electrons are able to move between the drain region 32 and the source region 34 via the series of the channel (CH) and the two-dimensional electron gas layer (2DEG).

(2) In the HEMT 10, the MIS structure 40 makes contact with a portion of the source region 34, while the heterostructure 25 makes contact with the MIS structure 40 and the drain region 32. The breakdown voltage of the HEMT 10 depends on the distance between the MIS structure 40 and the drain region 32, an not on the distance between the MIS structure 40 and the source region 34. Hence, the distance between the MIS structure 40 and the source region 34 does not need to be secured. By configuring the MIS structure 40 to make contact with a part of the source region 34, the spatial efficiency can be improved without degrading the voltage resistance.

(Method of Producing the HEMT 10)

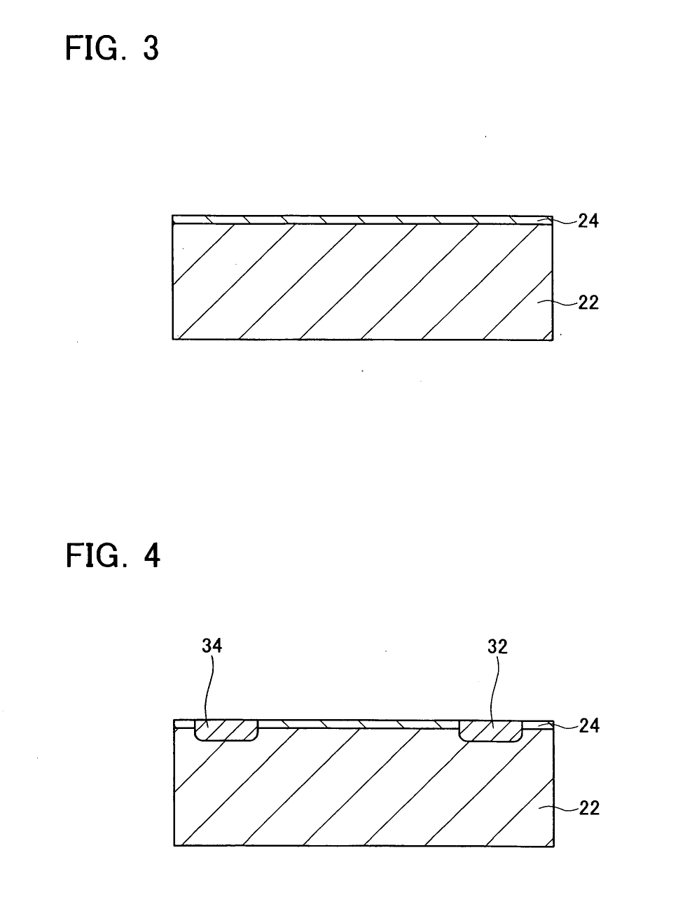

First, as shown in FIG. 3, the first semiconductor region 22 of gallium nitride (GaN) is prepared. Then, by using the MOCVD method, the second semiconductor region 24 of about 50 nm thickness is grown on the surface of the first semiconductor region 22.

Then, as shown in FIG. 4, by using the ion implantation technique, silicon is locally introduced through the second semiconductor region 24 and into the first semiconductor region 22. In this process, the drain region 32 and the source region 34 are formed.

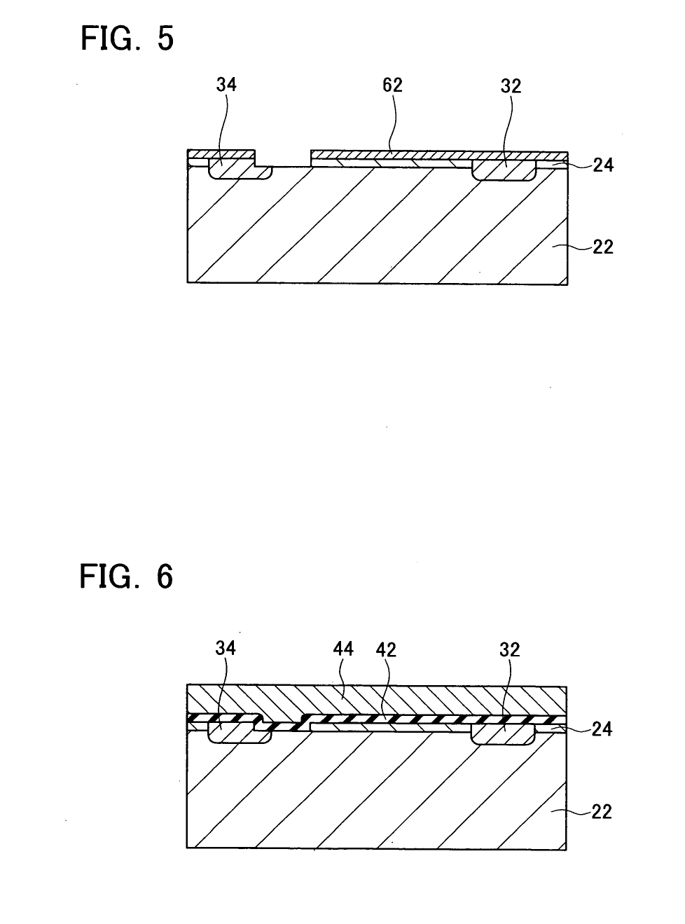

As shown in FIG. 5, a mask 62 is patterned on the surface of the second semiconductor region 24. The portion of the source region 34 and the second semiconductor region 24 exposed through an opening hole of the mask 62 are removed. Thus, at least, the corresponding portion of the surface of the first semiconductor region 22 is exposed. The mask 62 is then removed.

Then, as shown in FIG. 6, by using the CVD method, the gate insulating membrane 42 is formed on the surface of the second semiconductor region 24 and the first semiconductor region 22 exposed from the concave. The thickness of the gate insulating membrane 42 is about 50 nm.

Then, by using the CVD method, the gate electrode 44 is formed on the surface of the gate insulating membrane 42. Then, after removing a portion of the gate insulating membrane 42 and the gate electrode 44, the HEMT 10 can be produced. In FIG. 1, the gate insulating membrane 42 is formed merely under the gate electrode 44. However, the gate insulating membrane 42 may cover the area between the source region 34 and the drain region 32.

### Second Embodiment

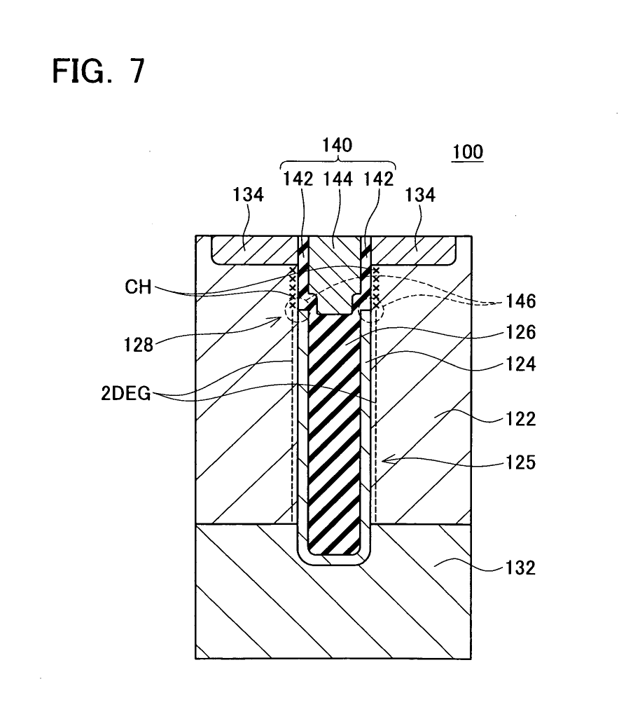

FIG. 7 shows a schematic sectional view of the relevant part of the HEMT 100. The HEMT 100 is of a type which the current is conducted in the vertical direction.

The HEMT 100 comprises a drain region 132 (which is an example of a high voltage side region), a first semiconductor region 122 formed on the drain region 132, and a source region 134 formed on the first semiconductor region 122. The source region 134 is separated from the drain region 132 by the first semiconductor region 122.

The drain region 132 is composed of gallium nitride (GaN). The drain region 132 is an n⁺-type region introduced with highly concentrated silicon. The concentration of impurity of the drain region 132 is about 1×10¹⁸ cm⁻³. A drain electrode not shown in the figures is connected to the drain region 132. The drain electrode is adapted to be electrically connected to a high voltage of an electric source also not shown in the figures.

The first semiconductor region 122 is composed of gallium nitride (GaN). The process of producing the first semiconductor region 122 does not include a step of intentionally introducing impurity thereto. The concentration of impurity of the first semiconductor region 122 is maintained at a level less than 1×10¹⁴ cm⁻³.

The source region 134 is composed of gallium nitride (GaN). The source region 134 is an n⁺-type region introduced with highly concentrated silicon. The concentration of impurity of the source region 134 is about 1×10²⁰ cm⁻³. A source electrode not shown in the figures is connected to the source region 134. The source electrode is adapted to be electrically connected to a low voltage of the electric source.

The HEMT 100 further comprises a columnar region 128 penetrating the source region 134 and the first semiconductor region 122 and reaching into the drain region 132. The columnar region 128 includes a MIS structure 140, a second semiconductor region 124 and a buried insulating region 126. The MIS structure 140 is formed at the upper section of the columnar region 128 and is in contact with the source region 134. The second semiconductor region 124 and the buried insulating region 126 are formed at the lower section of the columnar region 128. A part of the second semiconductor region 124 and the buried insulating region 126 is protruding into the drain region 132. The second semiconductor region 124 is in contact with the drain region 132.

The MIS structure 140 includes a gate insulating membrane 142 and a gate electrode 144. The gate electrode 144 faces a portion of the side surface of the first semiconductor region 122 with the gate insulating membrane 142 therebetween. Thus, the gate electrode 144 is electrically insulated from the first semiconductor region 122 and the second semiconductor region 124. Silicon dioxide (SiO₂) is used for the gate insulating membrane 142. The thickness of the gate insulating membrane 142 is about 50 nm. A polysilicon with highly introduced impurity is used for the gate electrode 144.

The second semiconductor region 124 is composed of aluminum gallium nitride (AlGaN). The thickness of the second semiconductor region 124 is about 25 nm. The second semiconductor region 124 may or may not be introduced with impurities of n-type. The second semiconductor region 124 includes aluminum within the composition of the crystal. Thus, the band-gap of the second semiconductor region 124 is wider than that of the first semiconductor region 122. The first semiconductor region 122 and the second semiconductor region 124 form the heterostructure. Silicon dioxide is used for the buried insulating region 126. The buried insulating region 126 is covered by the second semiconductor region 124.

As shown in FIG. 7, the MIS structure 140 is arranged in between the drain region 132 and the source region 134. With this configuration, the second semiconductor region 124 arranged in between the drain region 132 and the source region 134 does not consecutively extend between the drain region 132 and the source region 134 in the vertical direction. The second semiconductor region 124 is hindered from directly connecting the drain region 132 and the source region 134 by the existence of the MIS structure 140. In another words, the drain region 132 and the source region 134 are capable of being electrically connected with a structure in which the MIS structure 140 and the heterostructure 125 are arranged in series.

The function and configuration of the HEMT 100 will be described below. The band-gap of the second semiconductor region 124 is wider than the band-gap of the first semiconductor region 122. For this reason, as shown in FIG. 7, a two-dimensional electron gas layer (2DEG) is formed at the heterojunction plane of the first semiconductor region 122 and the second semiconductor region 124. Of the heterojunction plane, the two-dimensional electron gas layer (2DEG) is formed on the first semiconductor region 122 side.

As mentioned before, the heterostructure 125 that is composed with the first semiconductor region 122 and the second semiconductor region 124 is not extended in all of the portions between the drain region 132 and the source region 134 in the vertical direction. The MIS structure 140 is arranged in between the drain region 132 and the source region 134. Hence, on the side surface of the first semiconductor region 122 where the MIS structure 140 is disposed, the two-dimensional electron gas layer (2DEG) is not formed. Thus, the two-dimensional electron gas layer (2DEG) is not consecutively extended in all of the portions between the drain region 132 and the source region 134 in the vertical direction.

On the side surface of the first semiconductor region 122 that faces the side surface of the MIS structure 140, a channel (CH) is formed with the voltage applied to the gate electrode 144. The channel (CH) is not inducted when no voltage is applied to the gate electrode 144. The channel (CH) is inducted when positive gate voltage is applied to the gate electrode 144. In a case where the channel (CH) is inducted, the interval between the drain region 132 and the source region 134 is electrically connected with the series of the channel (CH) and the two-dimensional electron gas layer (2DEG). When the channel (CH) and the two-dimensional electron gas layer (2DEG) are consecutively connected in series, the electrons are able to move between the drain region 132 and the source region 134 in the vertical direction.

Thus, the HEMT 100 is switched off when no voltage is applied to the gate electrode 144, while the HEMT 100 is switched on when positive voltage is applied to the gate electrode 144. The HEMT 100 is able to function under the normally-off state.

Other characteristics of The HEMT 100 are described below.

(1) In the HEMT 100, the impurity concentration of the first semiconductor region 122 is maintained at a level less than 1×10¹⁴ cm⁻³. The first semiconductor region 122 having the aforementioned impurity concentration can substantially be regarded as an insulator. For such a configuration, the electric field strength in between the drain region 132 and the MIS structure 140 is leveled. Localized electric field concentration can be prevented. Especially, as indicated in FIG. 7, the electric field concentration at the corner section 146 of the gate insulating membrane 142 of the MIS structure 140 can be effectively relieved. As its result, the destruction of the gate insulating membrane 142 is prevented. Even in a case where the impurity concentration of the first semiconductor region 122 is less than 1×10¹⁴ cm⁻³, the electrons are able to move between the drain region 132 and the source region 134 via the series of the channel (CH) and the two-dimensional electron gas layer (2DEG).

(2) In the HEMT 100, the MIS structure 140 makes contact with a portion of the source region 134, while the heterostructure 125 makes contact with the MIS structure 140 and the drain region 132. The breakdown voltage of the HEMT 100 depends on the distance between the MIS structure 140 and the drain region 132, an not on the distance between the MIS structure 140 and the source region 134. Hence, the distance between the MIS structure 140 and the source region 134 does not need to be secured. By configuring the MIS structure 140 to make contact with a part of the source region 134, the spatial efficiency can be improved without degrading the voltage resistance.

(Method of Producing the HEMT 100)

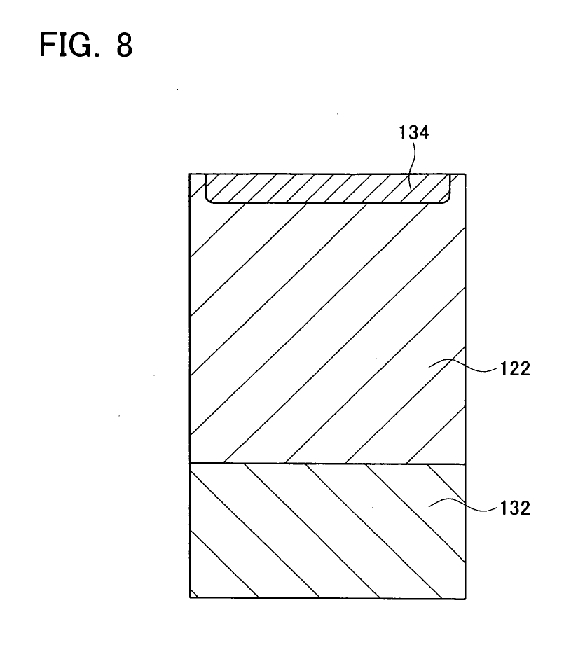

First, as shown in FIG. 8, a semiconductor substrate in which the drain region 132 and the first semiconductor region 122 are stacked is prepared. The first semiconductor region 122 is formed on the drain region 132 by using the epitaxial growth technique. Then, by using the ion implantation technique, silicon is locally introduced into the surface section of the first semiconductor region 122. In this process, the source region 134 is formed.

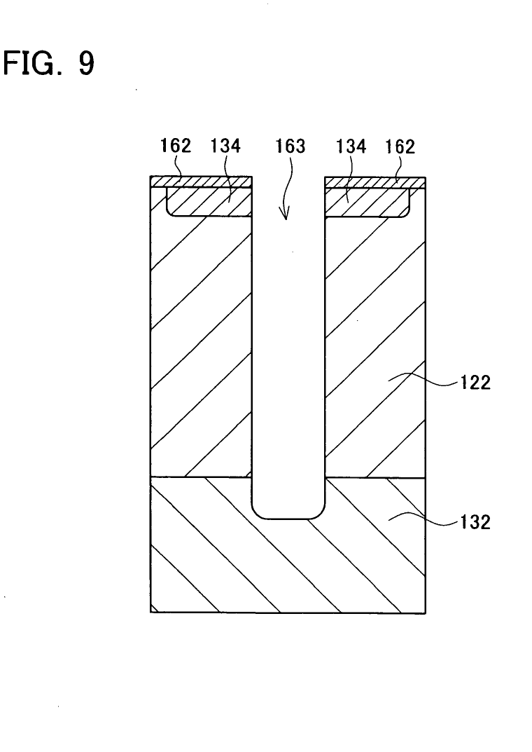

Then, as shown in FIG. 9, a mask 162 is patterned on the surface of the first semiconductor region 122 and the source region 134. Then, by using the dry etching technique, a trench 163 is formed from an opening hole of the mask 162. The trench 163 has the width of 1 μm and depth of 10 μm. The trench 163 penetrates through the source region 134 and the first semiconductor region 122, and reaching into the drain region 132.

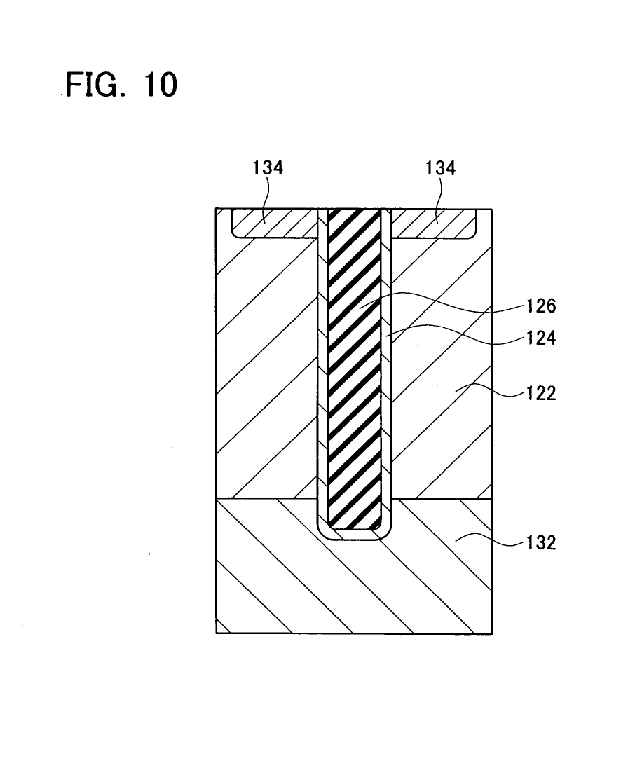

Then, as shown in FIG. 10, by using the MOCVD method, the second semiconductor region 124 of about 25 nm thickness is grown on the inner surface of the trench 163. Then, by using either the CVD method or the spin-on glass method, the inside of the trench 163 is filled with the buried insulating region 126.

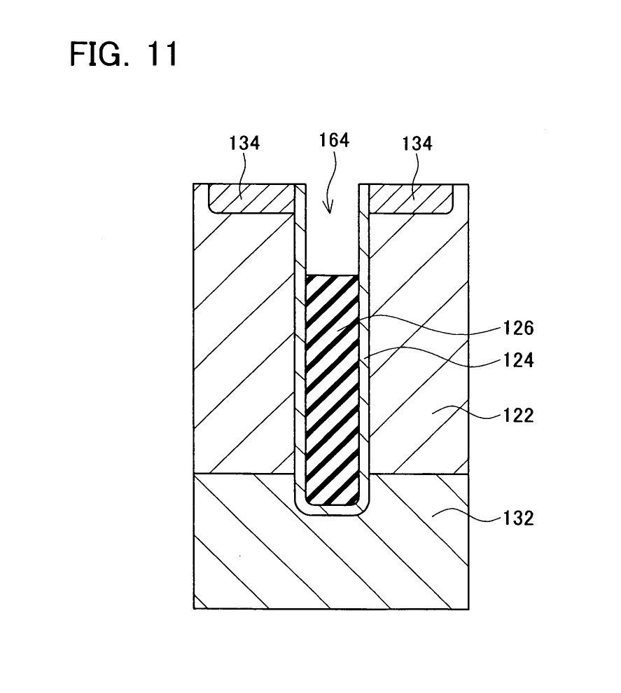

Then, as shown in FIG. 11, by using the wet etching technique using hydrogen fluoride (HF), a part of the buried insulating region 126 is selectively removed to the depth of 1 μm from the surface, and a trench 164 is formed.

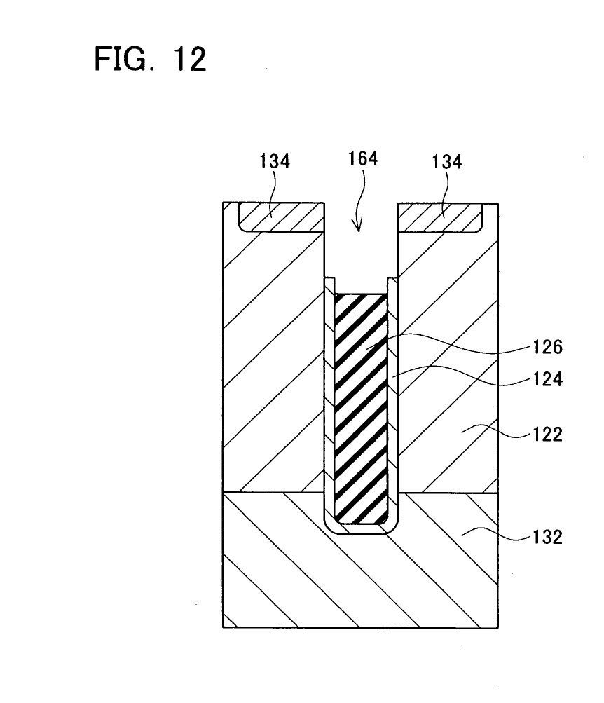

Then, as shown in FIG. 12, by using the wet etching technique using tetramethylammoniumhydroxide ((CH3)4NOH:TMAH), the second semiconductor region 124 that is exposed within the trench 164 is selectively removed.

With the wet etching technique using hydrogen fluoride (HF) and tetramethylammoniumhydroxide (TMAH), the trench 164 can be formed self-aligned.

Then, by using the CVD method, the gate insulating membrane 142 with the thickness of 50 nm is formed on the inner surface of the trench 164, and then again by using the CVD method, the gate electrode 144 is filled into the trench 164. With the aforementioned processes, the HEMT 100 as shown in FIG. 7 can be produced.

### A Variant of the Second Embodiment

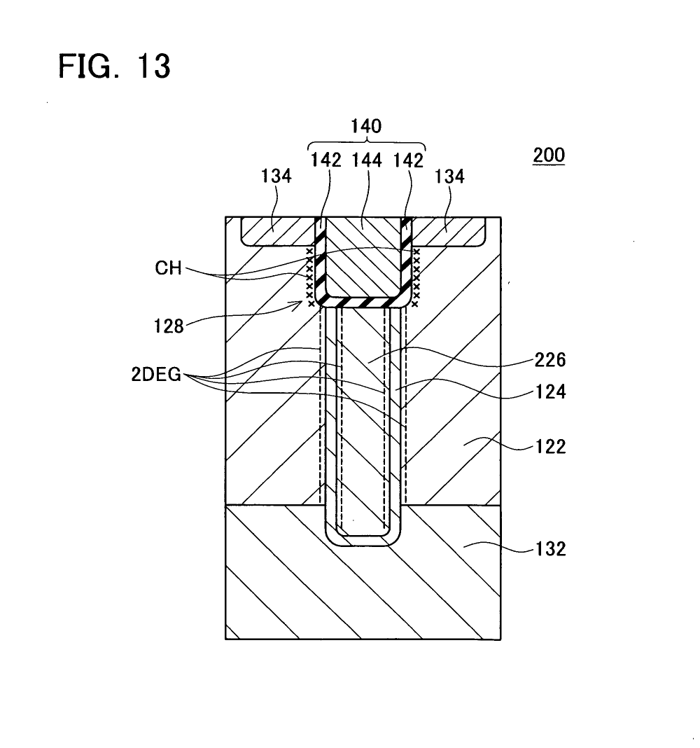

FIG. 13 shows a schematic sectional view of the relevant part of a HEMT 200. The HEMT 200 is a variant of the HEMT 100 of the second embodiment. In FIGS. 13-15, the configurations common to the HEMT 100 and HEMT 200 has the same numberings as the figures of the second embodiment. The explanations corresponding to such common configurations are abbreviated in the description below.

The HEMT 200 is characterized in that it includes a third semiconductor region 226 in place of the buried insulating region 126 of the HEMT 100. The third semiconductor region 226 is composed of gallium nitride (GaN). Thus, the band-gap of the second semiconductor region 124 is wider than the band-gap of the third semiconductor region 226. The impurity concentration of the third semiconductor region 226 is maintained at a level less than 1×10¹⁴ cm⁻³.

As shown in FIG. 13, in the HEMT 200, a two-dimensional electron gas layer (2DEG) is formed not only at the heterojunction plane of the first semiconductor region 122 and the second semiconductor region 124 but also at the heterojunction plane of the second semiconductor region 124 and the third semiconductor region 226. Hence, the HEMT 200 is able to function with low on-resistance.

(Method of Producing the HEMT 200)

Same processes as shown in FIGS. 8 and 9 are applied to the production the HEMT 200.

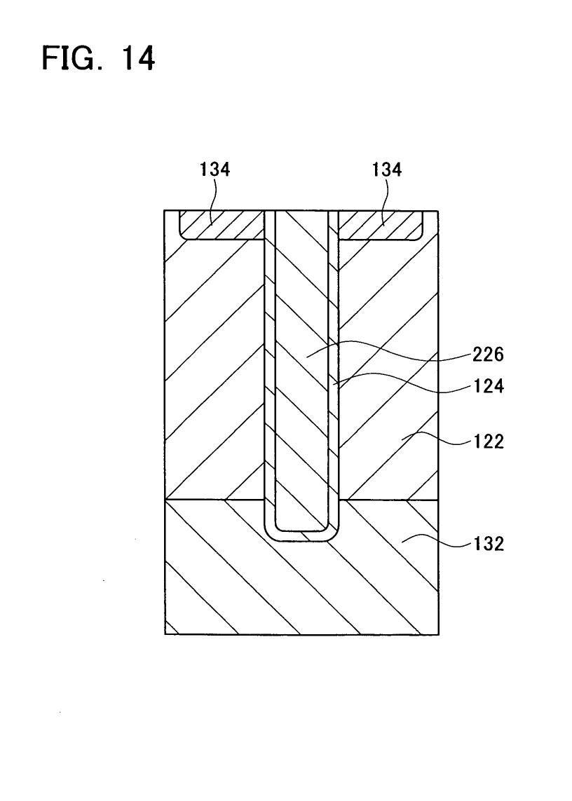

Then, as shown in FIG. 14, by using the MOCVD method, the second semiconductor region 124 of about 25 nm thickness is grown on the inner surface of the trench 163. Then, by using the MOCVD method, the inside of the trench 163 is filled with the third semiconductor region 226.

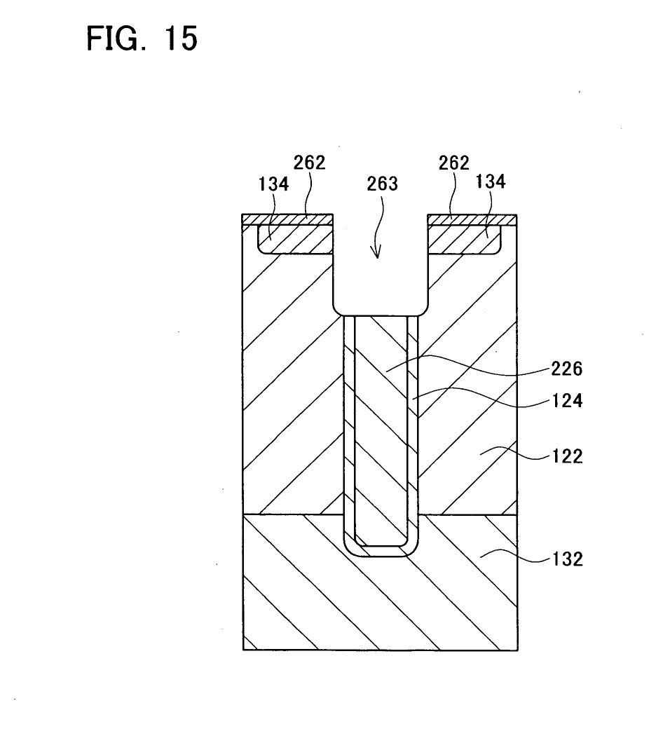

Then, as shown in FIG. 15, a mask 262 is patterned on the surface of the first semiconductor region 122 so as to expose the second semiconductor region 124 and the third semiconductor region 226 from an opening formed on the mask 262. Then, by using the dry etching technique, a trench 263 is formed from the opening hole of the mask 262. The trench 263 has the width of 1.6 μm and depth of 1 μm. The trench 263 is formed so that its occupying area seen in a plan view is larger than that of the second semiconductor region 124 and the third semiconductor region 226. The parts of the second semiconductor region 124 and the third semiconductor region 226 in their depth direction are removed.

Then, by using the CVD method, the gate insulating membrane 142 with the thickness of 50 nm is formed on the inner surface of the trench 263, and then again by using the CVD method, the gate electrode 144 is filled into the trench 263. With the aforementioned processes, the HEMT 200 as shown in FIG. 13 can be produced.

Specific examples were described in detail above, however these are simply illustrations, and do not limit the scope of the claims. The specific examples illustrated above include various modifications and changes that are within the technology disclosed in the present specification. In addition, the technological components described in the present specification or the drawings exhibit technological utility individually or in various combinations, and are not limited to the combinations disclosed in the claims at the time of application. Furthermore, the technology illustrated in the present specification or the drawings may simultaneously achieve a plurality of objects, and has technological utility by achieving one of these objects.

What is claimed is:

1. A HEMT comprising:
a high voltage side region adapted to be electrically connected to a high voltage of an electric source;
a low voltage side region adapted to be electrically connected to a low voltage of the electric source;
a first semiconductor region disposed between the high voltage side region and the low voltage side region;
a MIS structure including a gate electrode and an insulating region, the gate electrode facing a portion of a surface of the first semiconductor region with the insulating region therebetween; and
a heterostructure including a second semiconductor region which makes contact with a rest portion of the surface of the first semiconductor region and has a wider band-gap than the first semiconductor region,
wherein the high voltage side region and the low voltage side region are capable of being electrically connected with a structure including the MIS structure and the heterostructure arranged in series.

2. The HEMT according to claim 1, wherein
the MIS structure makes contact with the low voltage side region, and
the heterostructure makes contact with the MIS structure and the high voltage side region.

3. The HEMT according to claim 1, wherein
the first semiconductor region and the second semiconductor region are group-III nitride semiconductor.

4. The HEMT according to claim 1, wherein
an impurity concentration of the first semiconductor region is equal to or less than 1×10¹⁴ cm⁻³.

5. A HEMT comprising:
a high voltage side region adapted to be electrically connected to a high voltage of an electric source;
a first semiconductor region disposed on the high voltage side region;
a low voltage side region disposed on the first semiconductor region, the low voltage side region being separated from the high voltage side region by the first semiconductor region, and the low voltage side region being adapted to be electrically connected to a low voltage of the electric source; and
a columnar region penetrating the first semiconductor region and extending between the high voltage side region and the low voltage side region, wherein
the columnar region comprises:
a MIS structure including a gate electrode and an insulating region, the gate electrode facing a portion of a side surface of the first semiconductor region with the insulating region therebetween; and
a heterostructure including a second semiconductor region which makes contact with a rest portion of the side surface of the first semiconductor region and has a wider band-gap than the first semiconductor region,
wherein the high voltage side region and the low voltage side region are capable of being electrically connected with a structure including the MIS structure and the heterostructure arranged in series.

6. The HEMT according to claim 5, wherein
the MIS structure makes contact with the low voltage side region, and
the heterostructure makes contact with the MIS structure and the high voltage side region.

7. The HEMT according to claim 5, wherein
the first semiconductor region and the second semiconductor region are group-III nitride semiconductor.

8. The HEMT according to claim 5, wherein
an impurity concentration of the first semiconductor region is equal to or less than 1×10¹⁴ cm⁻³.

9. The HEMT according to claim 5, further comprising:
a third semiconductor region facing the first semiconductor region with the second semiconductor region therebetween, the third semiconductor region having a narrower band-gap than the second semiconductor region.

10. The HEMT according to claim 9, wherein
the first semiconductor region, the second semiconductor region and the third semiconductor region are group-III nitride semiconductor.

11. The HEMT according to claim 9, wherein
an impurity concentration of the first semiconductor region is equal to or less than 1×10¹⁴ cm⁻³, and
an impurity concentration of the third semiconductor region is equal to or less than 1×10¹⁴ cm⁻³.
